(19) United States
(12) Patent Application Publication
(10) Pub. No.: US 2024/0126178 A1
(43) Pub. Date: Apr. 18, 2024

(54) EXPOSURE APPARATUS, CONTROL METHOD, AND DEVICE MANUFACTURING METHOD

(71) Applicant: NIKON CORPORATION, Tokyo (JP)

(72) Inventors: Masaki KATO, Yokohama-shi (JP); Yasushi Mizuno, Saitama-shi (JP); Toshiharu Nakashima, Fukaya-shi (JP); Yoshihiko Fujimura, Kawasaki-shi (JP)

(73) Assignee: NIKON CORPORATION, Tokyo (JP)

(21) Appl. No.: 18/542,169

(22) Filed: Dec. 15, 2023

Related U.S. Application Data
(63) Continuation of application No. PCT/JP22/26201, filed on Jun. 30, 2022.

(30) Foreign Application Priority Data
Jul. 5, 2021 (JP) 2021-111804

(51) Int. Cl. G03F 7/00

(52) U.S. Cl. CPC G03F 7/70291; G03F 7/70258; G03F 7/70758

(57) ABSTRACT

An exposure apparatus includes a substrate holder configured to hold a substrate and move, a module including a spatial light modulator having light modulation elements that are two-dimensionally arranged, an illumination unit irradiating the spatial light modulator with illumination lights, and a projection unit guiding the illumination light from the light modulation elements to respective light irradiation areas that are two-dimensionally arranged on the substrate in first and second directions, and a control unit configured to drive the substrate holder in a scanning direction, wherein the light modulation elements are two-dimensionally arranged to be inclined at a predetermined angle θ (0°<θ<90°) with respect to the scanning direction and a non-scanning direction orthogonal to the scanning direction, and when a predetermined region of the substrate is exposed, the control unit scans the substrate holder at such a speed that spot positions are arranged in a staggered arrangement.

### CROSS-REFERENCE TO RELATED APPLICATION

This application is based upon and claims the benefit of priority of the prior International Patent Application No. PCT/JP2022/026201, filed on Jun. 30, 2022, the entire contents of which are incorporated herein by reference.

### FIELD

The present disclosure relates to an exposure apparatus, a control method, and a device manufacturing method.

### BACKGROUND

Conventionally, a step-and-repeat projection exposure apparatus (so-called stepper) or a step-and-scan projection exposure apparatus (so-called scanning stepper (also called scanner)) has been used in a lithography process for manufacturing a liquid crystal or organic EL display panel or electronic devices (micro devices) such as semiconductor elements (integrated circuits or the like). This type of exposure apparatus projects and exposes a mask pattern for electronic devices onto a photosensitive layer applied on the surface of a substrate to be exposed (hereinafter also simply referred to as a substrate) such as a glass substrate, a semiconductor wafer, a printed wiring board, or a resin film.

Since it takes time and cost to manufacture a mask substrate on which the mask pattern is fixedly formed, an exposure apparatus using a spatial light modulation element (variable mask pattern generator) such as a digital mirror device (DMD) in which a large number of micro-mirrors, which are finely displaced, are regularly arranged instead of the mask substrate is known as disclosed in, for example, Japanese Patent Application Laid-Open No. 2019-23748 (Patent Document 1). In the exposure apparatus disclosed in Patent Document 1, for example, illumination light obtained by mixing light from a laser diode (LD) with a wavelength of 375 nm and light from another LD with a wavelength of 405 nm using a multimode fiber bundle is emitted to a digital mirror device (DMD), and light reflected from each of a large number of tilt-controlled micromirrors is projected and exposed onto a substrate through an imaging optical system and a microlens array.

In the exposure apparatus, it is desired to achieve high-precision exposure at high throughput.

### SUMMARY

In one aspect of the present disclosure, there is provided an exposure apparatus including: a substrate holder configured to hold and move a substrate; a module including: a spatial light modulator including light modulation elements that are two-dimensionally arranged; an illumination unit configured to irradiate the spatial light modulator with illumination light; and a projection unit configured to guide the illumination light from the light modulation elements to respective light irradiation areas that are two-dimensionally arranged in a first direction and a second direction perpendicular to the first direction on the substrate; and a control unit configured to drive the substrate holder in a scanning direction, wherein the light modulation elements are two-dimensionally arranged so as to be inclined at a predetermined angle θ (0°<θ<90°) with respect to the scanning direction and a non-scanning direction orthogonal to the scanning direction, and wherein when a predetermined region of the substrate is exposed, the control unit scans the substrate holder at such a speed that spot positions on the predetermined region are arranged in a staggered arrangement, wherein the spot positions each indicate a center of the illumination light emitted from a corresponding one of the light modulation elements and irradiated to the predetermined region.

The configurations of the embodiments described below may be appropriately improved, and at least a part of the configurations may be replaced with another configuration. Furthermore, constituent elements whose arrangement is not particularly limited are not limited to the arrangement disclosed in the embodiment, and can be arranged at positions where their functions can be achieved.

### BRIEF DESCRIPTION OF DRAWINGS

FIG. 1 is a perspective view illustrating an overview of an external configuration of an exposure apparatus in accordance with an embodiment;

FIG. 2 illustrates an arrangement example of projection areas of DMDs projected onto a substrate by projection units of a plurality of exposure modules;

FIG. 3 is a view for describing a state of joint exposure by each of four specific projection areas in FIG. 2;

FIG. 4 is an optical layout diagram of a specific configuration of two exposure modules arranged in the X direction (scanning exposure direction) as viewed in the XZ plane;

FIG. 5A schematically illustrates a DMD, FIG. 5B illustrates the DMD when the power supply is OFF, FIG. 5C is a view for describing a mirror in an ON state, and FIG. 5D is a view for describing a mirror in an OFF state;

FIG. 6 is a functional block diagram illustrating a functional configuration of an exposure control device provided in the exposure apparatus;

FIG. 7 is a view schematically illustrating a projection area (light irradiation area group) and an exposure target region (region to which a line pattern is exposed) on a substrate;

FIG. 8 illustrates a rectangular region, which is a part of a linear exposure target region, and the projection area (light irradiation area group);

FIG. 9A to FIG. 9C are diagrams for describing an example of a case where spot positions are arranged in a square shape in the rectangular region;

FIG. 10A to FIG. 10C are diagrams for describing an example of a case where spot positions are arranged in a staggered manner in the rectangular region;

FIG. 11 illustrates arrangement examples of spot positions in staggered exposure;

FIG. 12 is a diagram for describing the staggered exposure in a joint section;

FIG. 13 is a diagram for describing an example in which two DMDs share the exposure in the joint section;

FIG. 14A to FIG. 14K are diagrams for describing position correction of a line pattern;

FIG. 15 is a graph presenting position measurement results when the position correction of the line pattern is performed using the methods of FIG. 14A to FIG. 14K;

FIG. 16A to FIG. 16K are diagrams (part 1) for describing line width adjustment of a line pattern;

FIG. 17A to FIG. 17L are diagrams (part 2) for describing the line width adjustment of the line pattern;

FIG. 18 is a graph presenting results of line width measurement when the line width adjustment of the line pattern is performed using the methods of FIG. 16A to FIG. 17L;

FIG. 19A to FIG. 19G are diagrams for describing correction based on distortion measurement results; and

FIG. 20A to FIG. 20G are diagrams for describing correction based on measurement results of illuminance distribution.

### DESCRIPTION OF EMBODIMENTS

A pattern exposure apparatus (hereinafter simply referred to as an exposure apparatus) in accordance with an embodiment will be described with reference to the drawings.

### Overall Configuration of Exposure Apparatus

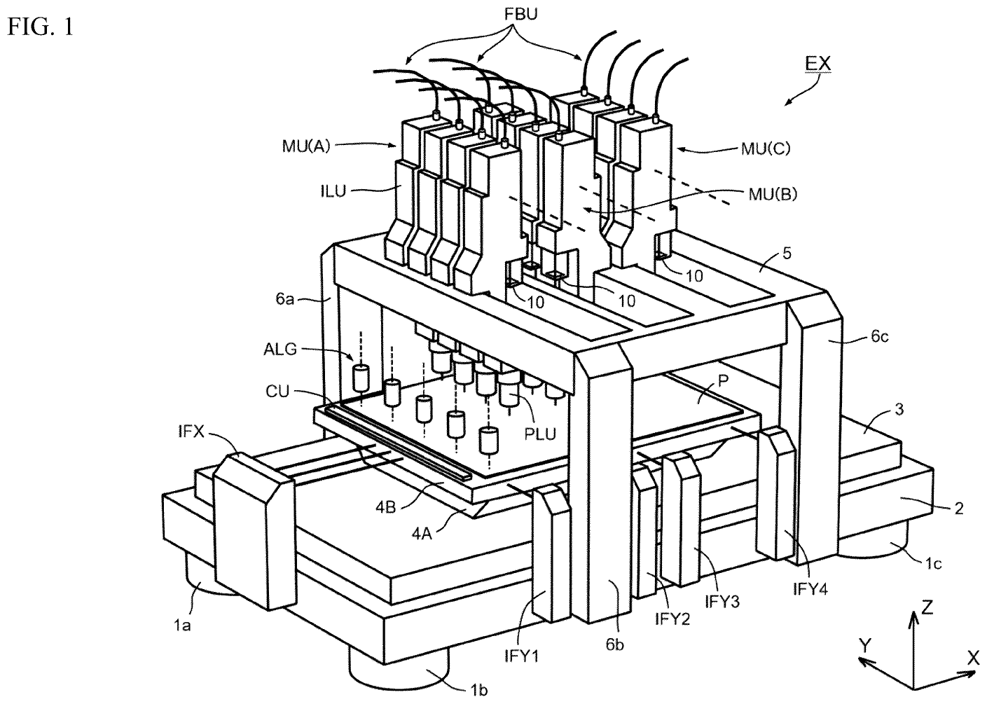

FIG. 1 is a perspective view illustrating an overview of the external configuration of an exposure apparatus EX in accordance with an embodiment. The exposure apparatus EX is an apparatus for imaging and projecting exposure light whose intensity distribution in space is dynamically modulated by a spatial light modulator (SLM) onto a substrate to be exposed. Examples of the spatial light modulator include a liquid crystal element, a digital micromirror device (DMD), and a magneto-optic spatial light modulator (MOSLM). The exposure apparatus EX of the present embodiment includes a DMD 10 as the spatial light modulator, but may include other spatial light modulators.

In a specific embodiment, the exposure apparatus EX is a step-and-scan projection exposure apparatus (scanner) that uses a rectangular (square) glass substrate used in a display device (flat panel display) or the like as an exposure object. The glass substrate is a substrate P for the flat panel display with at least one side or diagonal length of 500 mm or greater and a thickness of 1 mm or less. The exposure apparatus EX exposes a projected image of a pattern formed by the DMD onto a photosensitive layer (photoresist) formed with a constant thickness on the surface of the substrate P. The substrate P carried out from the exposure apparatus EX after the exposure is delivered to a predetermined process step (film forming step, etching step, plating step, or the like) after the developing step.

The exposure apparatus EX includes a stage device including: a pedestal 2 placed on active vibration isolation units 1a, 1b, 1c, and 1d (1d is not illustrated), a surface plate 3 placed on the pedestal 2, an XY stage 4A two dimensionally movable on the surface plate 3, a substrate holder 4B that holds the substrate P on a plane on the XY stage 4A by suction, and laser length measuring interferometers (hereinafter, also simply referred to as interferometers) IFX and IFY1 to IFY4 for measuring the two-dimensional movement positions of the substrate holder 4B (substrate P). Such a stage device is disclosed in, for example, U.S. Patent Publication No. 2010/0018950 and U.S. Patent Publication No. 2012/0057140.

In FIG. 1, the XY plane of the orthogonal coordinate system XYZ is set to be parallel to the flat surface of the surface plate 3 of the stage device, and the XY stage 4A is set to be capable of translational movement within the XY plane. Further, in the present embodiment, the direction parallel to the X axis of the coordinate system XYZ is set as the scanning movement direction of the substrate P (XY stage 4A) during scan exposure. The movement position of the substrate P in the X-axis direction is sequentially measured by the interferometer IFX, and the movement position in the Y-axis direction is sequentially measured by at least one (preferably two) or more of the four interferometers IFY1 to IFY4. The substrate holder 4B is configured to be slightly movable in the direction of the Z axis perpendicular to the XY plane with respect to the XY stage 4A and to be slightly tiltable in a desired direction with respect to the XY plane, and focus adjustment and leveling (parallelism) adjustment between the surface of the substrate P and the imaging plane of the projected pattern are actively performed. Further, the substrate holder 4B is configured to be capable of slightly rotating (Oz rotation) around an axial line parallel to the Z axis to actively adjust the tilt of the substrate P in the XY plane.

The exposure apparatus EX further includes an optical surface plate 5 that holds a plurality of exposure (drawing) modules MU(A), MU(B), and MU(C), and main columns 6a, 6b, 6c, and 6d (6d is not illustrated) that support the optical surface plate 5 from the pedestal 2. Each of the exposure modules MU(A), MU(B), and MU(C) is mounted on the +Z direction side of the optical surface plate 5. The exposure modules MU(A), MU(B), and MU(C) may be individually mounted on the optical surface plate 5, or may be mounted on the optical surface plate 5 in a state where rigidity is increased by coupling two or more exposure modules to each other. Each of the exposure modules MU(A), MU(B), and MU(C) includes an illumination unit ILU that is mounted on the +Z direction side of the optical surface plate 5 and receives illumination light from an optical fiber unit FBU, and a projection unit PLU that is mounted on the −Z direction side of the optical surface plate 5 and has an optical axis parallel to the Z axis. Further, each of the exposure modules MU(A), MU(B), and MU(C) includes the DMD 10 as a light modulation unit that reflects the illumination light from the illumination unit ILU in the −Z direction and makes the illumination light enter the projection unit PLU. A detailed configuration of the exposure module including the illumination unit ILU, the DMD 10, and the projection unit PLU will be described later.

A plurality of alignment systems (microscopes) ALG that detect alignment marks formed at a plurality of predetermined positions on the substrate P are mounted at the −Z direction side of the optical surface plate 5 of the exposure apparatus EX. In addition, a calibration reference unit CU for calibration is provided at the end portion in the −X direction on the substrate holder 4B. Calibration includes at least one of the following: check (calibration) of the relative positional relationship in the XY plane of the detection field of each of the alignment systems ALG, check (calibration) of the baseline error between the projection position of the pattern image projected from the projection unit PLU of each of the exposure modules MU(A), MU(B), and MU(C) and the position of the detection field of each of the alignment systems ALG, and check of the position and image quality of the pattern image projected from the projection unit PLU. Although some are not illustrated in FIG. 1, in each of the exposure modules MU(A), MU(B), and MU(C), nine modules are arranged at regular intervals in the Y direction as an example, but the number of modules may be less than nine or may be greater than nine. Although the exposure modules are arranged in three rows in the X-axis direction in FIG. 1, the number of rows of the exposure modules arranged in the X-axis direction may be two or less or four or more.

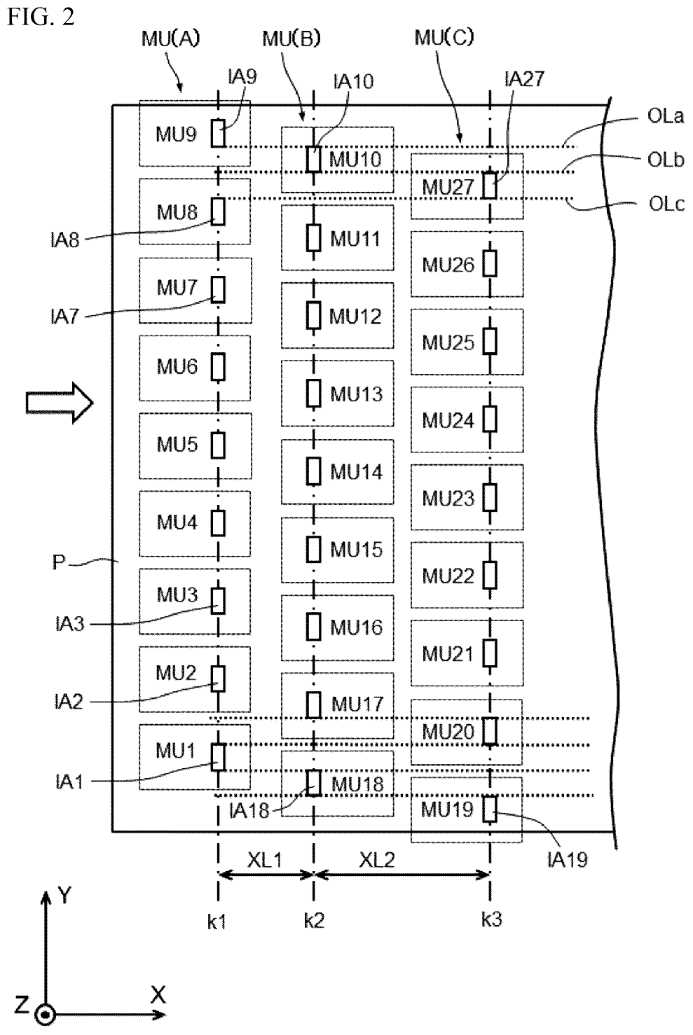

FIG. 2 illustrates an arrangement example of projection areas IAn of the DMDs 10 projected onto the substrate P by the projection units PLU of each of the exposure modules MU(A), MU(B), and MU(C), and the orthogonal coordinate system XYZ is set as in FIG. 1. It can be said that the projection area IAn is an irradiation area (group of light irradiation areas) of the illumination lights reflected by a plurality of micromirrors 10a of the DMD 10 and guided onto the substrate P by the projection unit PLU. In the present embodiment, each of the exposure module MU(A) in the first column, the exposure module MU(B) in the second column, and the exposure module MU(C) in the third column, which are arranged to be spaced apart from each other in the X direction, is composed of nine modules arranged in the Y direction. The exposure module MU(A) is composed of nine modules MU1 to MU9 arranged in the +Y direction, the exposure module MU(B) is composed of nine modules MU10 to MU18 arranged in the −Y direction, and the exposure module MU(C) is composed of nine modules MU19 to MU27 arranged in the +Y direction. The modules MU1 to MU27 all have the same configuration. When the exposure module MU(A) and the exposure module MU(B) face each other in the X direction, the exposure module MU(B) and the exposure module MU(C) are back-to-back in the X direction.

In FIG. 2, the shapes of projection areas IA1, IA2, IA3, . . . , IA27 (also expressed as IAn where n is 1 to 27) by the respective modules MU1 to MU27 are rectangles extending in the Y direction with an aspect ratio of approximately 1:2 as an example. In the present embodiment, as the substrate P is scanned and moved in the +X direction, the joint exposure is performed in the end portions in the −Y direction of the respective projection areas IA1 to IA9 in the first column and the end portions in the +Y direction of the respective projection areas IA10 to IA18 in the second column. Then, the regions on the substrate P that are not exposed by each of the projection areas IA1 to IA18 of the first column and the second column are subjected to joint exposure by the respective projection areas IA19 to IA27 of the third column. The center point of each of the projection areas IA1 to IA9 in the first column is located on a line k1 parallel to the Y axis, the center point of each of the projection areas IA10 to IA18 in the second column is located on a line k2 parallel to the Y axis, and the center point of each of the projection areas IA19 to IA27 in the third column is located on a line k3 parallel to the Y axis. A distance between the line k1 and the line k2 in the X direction is set to a distance XL1, and a distance between the line k2 and the line k3 in the X direction is set to a distance XL2.

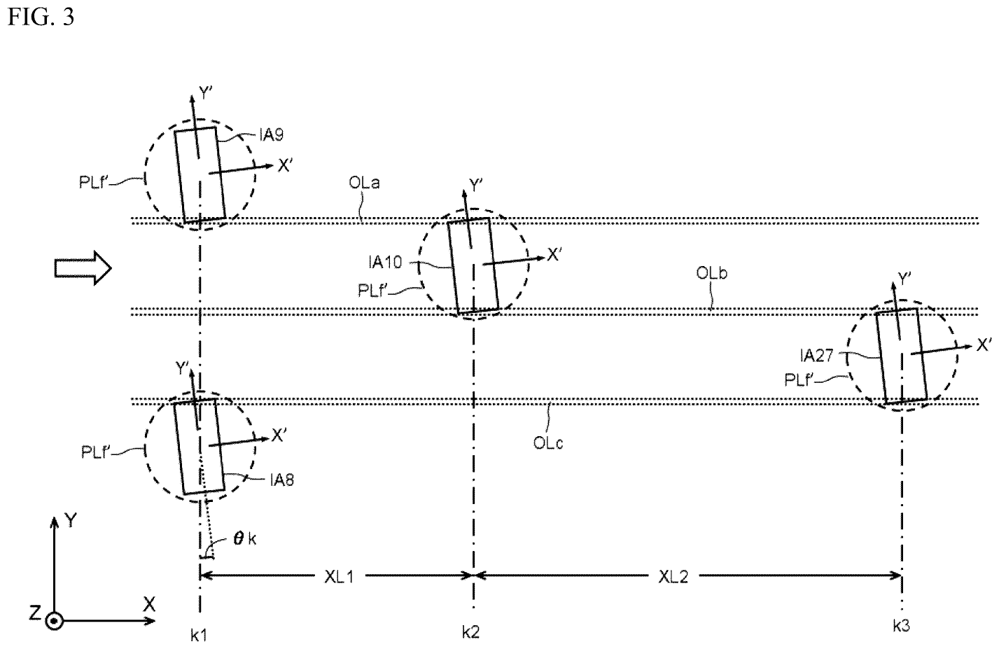

The state of joint exposure will be described with reference to FIG. 3, where the joint section between the end portion in the −Y direction of the projection area IA9 and the end portion in the +Y direction of the projection area IA10 is OLa, the joint section between the end portion in the −Y direction of the projection area IA10 and the end portion in the +Y direction of the projection area IA27 is OLb, and the joint section between the end portion in the +Y direction of the projection area IA8 and the end portion in the −Y direction of the projection area IA27 is OLc. In FIG. 3, the orthogonal coordinate system XYZ is set in the same manner as in FIG. 1 and FIG. 2, and the coordinate systems X′Y′ in the projection areas IA8, IA9, IA10, IA27 (and all other projection areas IAn) are set to be inclined at an angle θk (0°<θk<90°) with respect to the X axis and the Y axis (lines k1 to k3) of the orthogonal coordinate system XYZ. That is, areas (light irradiation areas) on the substrate P onto which illumination lights reflected by a large number of micromirrors of the DMD 10 are projected are two-dimensionally arranged along the X′ axis and the Y′ axis.

The circular area encompassing each of the projection areas IA8, IA9, IA10, IA27 (and all other projection areas IAn) in FIG. 3 represents a circular image field PLf′ of the projection unit PLU. In the joint section OLa, the projected images (light irradiation areas) of the micromirrors arranged obliquely (at the angle θk) in the end portion in the −Y′ direction of the projection area IA9 and the projected images (light irradiation areas) of the micromirrors arranged obliquely (at the angle θk) in the end portion of the projection area IA10 in the +Y′ direction are set so as to overlap each other. In the joint section OLb, the projected images (light irradiation areas) of the micromirrors arranged obliquely (at the angle θk) in the end portion in the −Y′ direction of the projection area IA10 and the projected images (light irradiation areas) of the micromirrors arranged obliquely (at the angle θk) in the end portion of the projection area IA27 in the +Y′ direction are set so as to overlap each other. Similarly, in the joint section OLc, the projected images (light irradiation areas) of the micromirrors obliquely arranged (at the angle θk) in the end portion in the +Y′ direction of the projection area IA8 and the projected images (light irradiation areas) of the micromirrors obliquely arranged (at the angle θk) in the end portion in the −Y′ direction of the projection area IA27 are set so as to overlap each other.

### Configuration of Illumination Unit

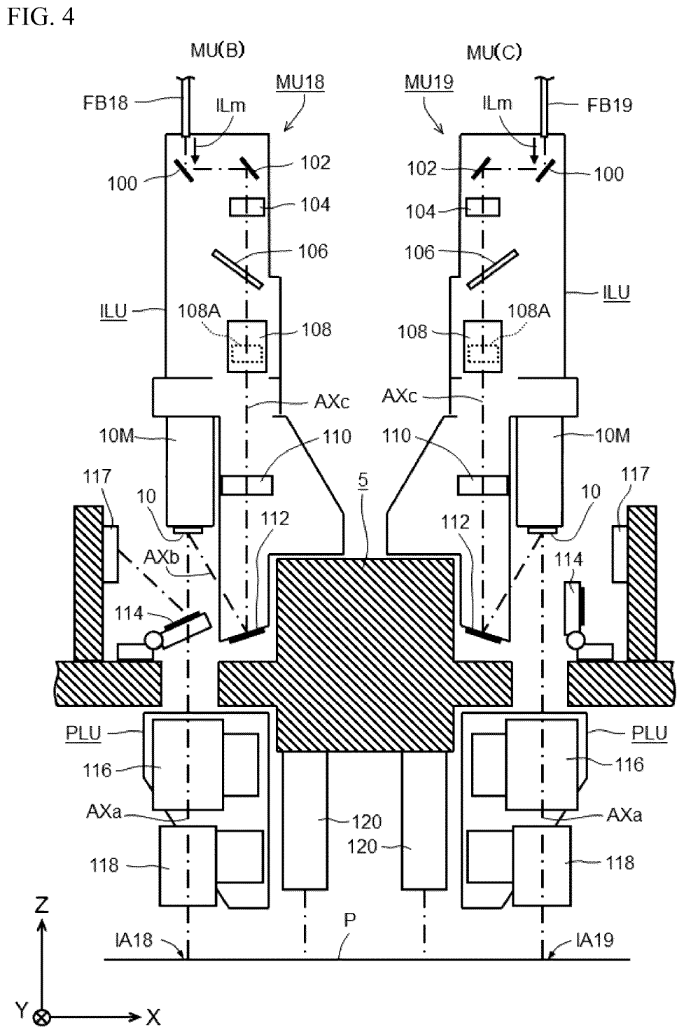

FIG. 4 is an optical layout diagram of a specific configuration of the module MU18 in the exposure module MU(B) and the module MU19 in the exposure module MU(C) illustrated in FIG. 1 and FIG. 2 as viewed in the XZ plane. The orthogonal coordinate system XYZ in FIG. 4 is set to be the same as the orthogonal coordinate system XYZ in FIG. 1 to FIG. 3. As is apparent from the arrangement of the modules in the XY plane illustrated in FIG. 2, the module MU18 is displaced from the module MU19 by a predetermined distance in the +Y direction and is disposed back-to-back with the module MU19. Since each optical member in the module MU18 and each optical member in the module MU19 are made of the same material and have the same configuration, the optical configuration of the module MU18 will be mainly described in detail here. The optical fiber unit FBU illustrated in FIG. 1 includes 27 optical fiber bundles FB1 to FB27 corresponding to the 27 modules MU1 to MU27 illustrated in FIG. 2, respectively.

The illumination unit ILU of the module MU18 includes: a mirror 100 that reflects the illumination light ILm traveling in the −Z direction from the emission end of the optical fiber bundle FB18; a mirror 102 that reflects the illumination light ILm from the mirror 100 in the −Z direction; an input lens system 104 that acts as a collimator lens; an illuminance adjustment filter 106; an optical integrator 108 that includes a micro fly eye (MFE) lens and a field lens; a condenser lens system 110; and an inclined mirror 112 that reflects the illumination light ILm from the condenser lens system 110 toward the DMD 10. The mirror 102, the input lens system 104, the optical integrator 108, the condenser lens system 110, and the inclined mirror 112 are arranged along an optical axis AXc parallel to the Z axis.

The optical fiber bundle FB18 is composed of one optical fiber line or a bundle of multiple optical fiber lines. The illumination light ILm emitted from the emission end of the optical fiber bundle FB18 (each of the optical fiber lines) is set to have a numerical aperture (NA, also referred to as a spread angle) such that the illumination light ILm enters the input lens system 104 in the subsequent stage without being subjected to vignetting. The position of the front focal point of the input lens system 104 is set to be the same as the position of the emission end of the optical fiber bundle FB18 in terms of design. Further, the position of the rear focal point of the input lens system 104 is set so that the illumination light ILm from a single or multiple point light sources formed at the emission end of the optical fiber bundle FB18 is superimposed on the incident surface side of an MFE lens 108A of the optical integrator 108. Therefore, the incident surface of the MFE lens 108A is Koehler-illuminated with the illumination light ILm from the emission end of the optical fiber bundle FB18. In the initial state, the geometric center point of the emission end of the optical fiber bundle FB18 in the XY plane is located on the optical axis AXc, and the principal ray (center line) of the illumination light ILm from the point light source at the emission end of the optical fiber is parallel to (or coaxial with) the optical axis AXc.

The illumination light ILm from the input lens system 104 is attenuated in illuminance by a freely-selected value in a range of 0% to 90% by the illuminance adjustment filter 106, and then passes through the optical integrator 108 (the MFE lens 108A, the field lens, and the like) to enter the condenser lens system 110. The MFE lens 108A is formed by two-dimensionally arranging a large number of rectangular microlenses of several tens of μm square, and the overall shape thereof is set to be substantially similar to the overall shape of the mirror surface of the DMD 10 (the aspect ratio is about 1:2) in the XY plane. The position of the front focal point of the condenser lens system 110 is set so as to be substantially the same as the position of the emission surface of the MFE lens 108A. Therefore, the respective illumination lights from the point light sources formed at the respective emission sides of the large number of microlenses of the MFE lens 108A are converted into substantially parallel light beams by the condenser lens system 110, reflected by the inclined mirror 112, and then superimposed on each other on the DMD 10 to form a uniform illuminance distribution. On the emission surface of the MFE lens 108A, a surface light source in which a large number of point light sources (condensing points) are densely arranged in two dimensions is formed, so that the MFE lens 108A functions as a member that forms a surface light source.

In the module MU18 illustrated in FIG. 4, the optical axis AXc parallel to the Z axis passing through the condenser lens system 110 is bent by the inclined mirror 112 to reach the DMD 10, and the optical axis between the inclined mirror 112 and the DMD 10 is referred to as the optical axis AXb. In the present embodiment, a neutral plane including the center point of each of the large number of micromirrors of the DMD 10 is set to be parallel to the XY plane. Therefore, an angle between the normal line (parallel to the Z axis) of the neutral plane and the optical axis AXb is an incident angle θα of the illumination light ILm with respect to the DMD 10. The DMD 10 is mounted on the underside of a mount portion 10M fixed to the support column of the illumination unit ILU. In order to finely adjust the position and orientation of the DMD 10, the mount portion 10M is provided with a fine movement stage in which a parallel link mechanism and an extendable piezoelectric element are combined as disclosed in, for example, International Publication No. 2006/120927.

### Configuration of DMD

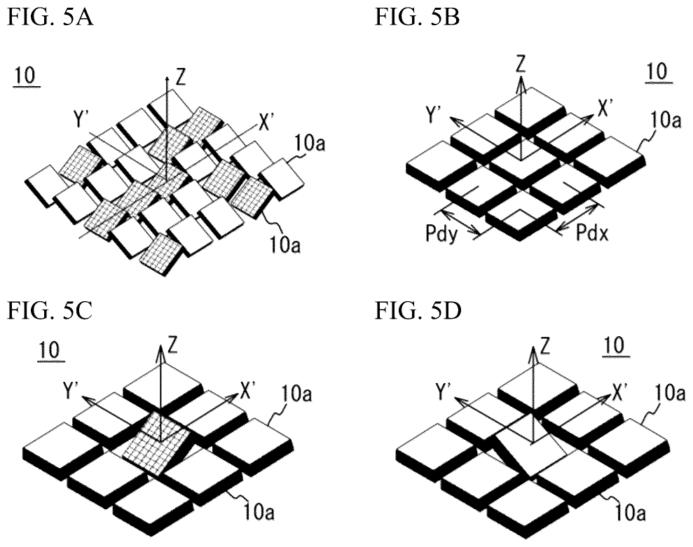

FIG. 5A schematically illustrates the DMD 10, FIG. 5B illustrates the DMD 10 when the power supply is OFF, FIG. 5C is a view for describing the mirror in an ON state, and FIG. 5D is a view for describing the mirror in an OFF state. In FIG. 5A to FIG. 5D, the mirrors in the ON state are indicated by hatching.

The DMD 10 has a plurality of micromirrors 10a of which the reflection angles can be controlled to change. In the present embodiment, the DMD 10 is of a roll-and-pitch drive type in which the ON and OFF states are switched by the inclination in the roll direction and the inclination in the pitch direction of the micromirror 10a.

As illustrated in FIG. 5A, when the power supply is OFF, the reflection surface of each micromirror 10a is set parallel to the X′Y′ plane. The arrangement pitch of the micromirrors 10a in the X′ direction is represented by Pdx (μm), and the arrangement pitch of the micromirrors 10a in the Y′ direction is represented by Pdy (μm). In practice, the arrangement pitch is set to Pdx=Pdy.

Each micromirror 10a becomes in the ON state by tilting about the Y′ axis. FIG. 5C illustrates a case where only the central micromirror 10a is in the ON state, and the other micromirrors 10a are in the neutral state (neither ON nor OFF state). Each micromirror 10a becomes in the OFF state by tilting about the X′ axis. FIG. 5D illustrates a case where only the central micromirror 10a is in the OFF state and the other micromirrors 10a are in neutral states. Although not illustrated for simplicity, the micromirror 10a in the ON state is driven to be inclined at a predetermined angle from the X′Y′ plane so that the illumination light emitted to the micromirror 10a in the ON state is reflected in the X direction of the XZ plane. The micromirror 10a in the OFF state is driven so as to be inclined at a predetermined angle from the X′Y′ plane so that the illumination light emitted to the micromirror 10a in the ON state is reflected in the Y direction in the YZ plane. The DMD 10 generates an exposure pattern by switching between ON and OFF states of each micromirror 10a.

The illumination light reflected by the mirror in the OFF state is absorbed by a light absorber (not illustrated).

Since the DMD 10 is described as an example of the spatial light modulator, the spatial light modulator is described as a reflective spatial light modulator that reflects laser light, but the spatial light modulator may be a transmissive spatial light modulator that transmits laser light or a diffractive spatial light modulator that diffracts laser light. The spatial light modulator can spatially and temporally modulate the laser light.

Referring back to FIG. 4, the illumination light ILm emitted to the micromirror 10a in the ON state among the micromirrors 10a of the DMD 10 is reflected in the X direction in the XZ plane so as to travel toward the projection unit PLU. On the other hand, the illumination light ILm emitted to the micromirror 10a in the OFF state among the micromirrors 10a of the DMD 10 is reflected in the Y direction in the YZ plane so as not to be directed to the projection unit PLU.

In the optical path between the DMD 10 and the projector unit PLU, a movable shutter 114 for shielding reflected light from the DMD 10 during a non-exposure period is provided so as to be insertable and removable. The movable shutter 114 is rotated to an angular position at which the movable shutter 114 is retracted from the optical path during the exposure period as illustrated in the module MU19, and is rotated to an angular position at which the movable shutter 114 is obliquely inserted into the optical path during the non-exposure period as illustrated in the module MU18. A reflection surface is formed at the DMD 10 side of the movable shutter 114, and the light from the DMD 10 reflected by the reflection surface is emitted to a light absorber 117. The light absorber 117 absorbs the optical energy of ultraviolet wavelengths (wavelengths equal to or shorter than the 400 nm) without re-reflecting and converts the optical energy into heat energy. Therefore, the light absorber 117 is also provided with a heat dissipation mechanism (heat dissipation fins or a cooling mechanism). Although not illustrated in FIG. 4, the light reflected from the micromirror 10a of the DMD 10 that is in the OFF state during the exposure period is absorbed by a similar light absorber (not illustrated in FIG. 4) disposed in the Y direction (direction perpendicular to the plane of paper of FIG. 4) with respect to the optical path between the DMD 10 and the projection unit PLU as described above.

### Configuration of Projection Unit

The projection unit PLU mounted on the underside of the optical surface plate 5 is configured as a both-side telecentric imaging projection lens system including a first lens group 116 and a second lens group 118 arranged along the optical axis AXa parallel to the Z axis. Each of the first lens group 116 and the second lens group 118 is configured to be translated by a fine actuator in a direction along the Z axis (optical axis AXa) with respect to a support column fixed to the underside of the optical surface plate 5. The projection magnification Mp of the imaging projection lens system formed by the first lens group 116 and the second lens group 118 is determined by the relationship between the arrangement pitch Pd of the micromirrors on the DMD 10 and the minimum line width (minimum pixel size) Pg of the pattern projected in the projection area IAn (n=1 to 27) on the substrate P.

As an example, when the required minimum line width (minimum pixel size) Pg is 1 μm and the arrangement pitch Pd of the micromirrors is 5.4 the projection magnification Mp is set to about ⅙ in consideration of the inclination angle θk in the XY plane of the projection area IAn (DMD 10) described above with reference to FIG. 3. The imaging projection lens system including the lens groups 116 and 118 vertically-inverts/horizontally-inverts the reduced image of the entire mirror surface of the DMD 10 and forms the resulting image in the projection area IA18 (IAn) on the substrate P.

The first lens group 116 of the projection unit PLU can be finely moved in the direction of the optical axis AXa by an actuator in order to finely adjust the projection magnification Mp (about ±several tens of ppm), and the second lens group 118 can be finely moved in the direction of the optical axis AXa by an actuator for fast focus adjustment. Further, in order to measure the positional change of the surface of the substrate P in the Z-axis direction with sub-micron accuracy or less, a plurality of obliquely incident light type focus sensors 120 are provided on the underside of the optical surface plate 5. The focus sensors 120 measure an overall positional change in the Z-axis direction of the substrate P, a positional change in the Z-axis direction of a partial area on the substrate P corresponding to each of the projection areas IAn (n=1 to 27), a partial inclination change of the substrate P, or the like.

The Illumination unit ILU and the projection unit PLU as described above are arranged so that the DMD 10 and the illumination unit ILU (at least the optical path portion from the mirror 102 to the mirror 112 along the optical axis AXc) in FIG. 4 are inclined at the angle θk as a whole in the XY plane because the projection area IAn is required to be inclined at the angle θk in the XY plane as described above with reference to FIG. 3.

The light beam (i.e., the spatially modulated light beam) formed only by the lights reflected from the micromirrors 10a in the ON state among the micromirrors 10a of the DMD 10 is emitted to the area on the substrate P optically conjugate to the micromirrors 10a through the projector unit PLU. In the following description, an area on the substrate P conjugate with each micromirror 10a is referred to as a light irradiation area, and a set of light irradiation areas is referred to as a light irradiation area group. The projection area IAn coincides with the light irradiation area group. That is, the light irradiation area group on the substrate P has a large number of light irradiation areas arranged in the two-dimensional directions (the X′ direction and the Y′ direction).

### Configuration of Exposure Control Device

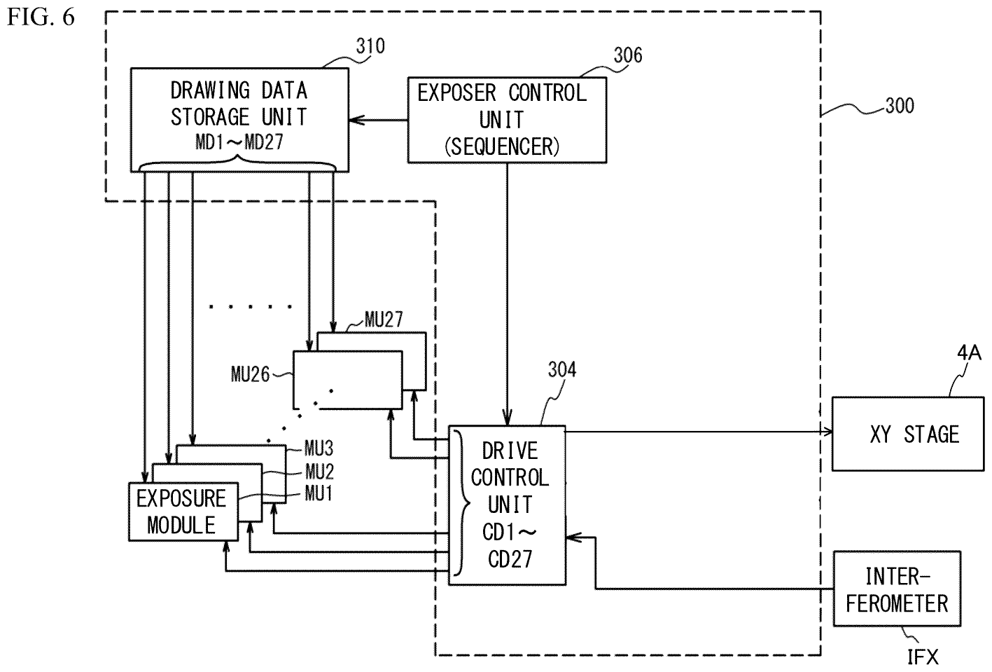

Various processes including the scanning exposure process performed in the exposure apparatus EX having the above-described configuration are controlled by an exposure control device 300. FIG. 6 is a functional block diagram illustrating a functional configuration of the exposure control device 300 provided in the exposure apparatus EX according to the present embodiment.

The exposure control device 300 includes a drawing data storage unit 310, a drive control unit 304, and an exposure control unit 306.

The drawing data storage unit 310 stores drawing data for patterns for a display panel to be exposed by the respective modules MUn (n=1 to 27). The drawing data storage unit 310 transmits drawing data MD1 to MD27 for pattern exposure to the DMDs 10 of the modules MU1 to MD27 illustrated in FIG. 2, respectively. The module MUn (n=1 to 27) selectively drives the micromirrors 10a of the DMD 10 based on the drawing data MDn to generate the pattern corresponding to the drawing data MDn, and projects and exposes the pattern onto the substrate P. That is, the drawing data is the data that causes each micromirror 10a of the DMD 10 to switch between the ON state and the OFF state.

The drive control unit 304 creates control signals CD1 to CD27 based on the measurement results of the interferometer IFX and transmits the control signals to the modules MU1 to MD27. The drive control unit 304 also scans the XY stage 4A in the scanning direction (X-axis direction) at a predetermined speed based on the measurement results of the interferometer IFX.

During scanning exposure, the modules MU1 to MD27 control the driving of the micromirrors 10a of the DMDs 10 based on the drawing data MD1 to MD27 and the control signals CD1 to CD27 transmitted from the drive control unit 304, respectively. Here, the control signals CD1 to CD27 are reset pulses. When receiving the reset pulse, each micromirror 10a takes a predetermined orientation in accordance with the drawing data MD1 to MD27. At this time, each time a reset pulse is received, each micromirror 10a changes its orientation to the orientation corresponding to the number of times the reset pulse is received.

In synchronization with the scanning exposure (movement position) of the substrate P, the exposure control unit (sequencer) 306 controls the transmission of the drawing data MD1 to MD27 from the drawing data storage unit 310 to the modules MU1 to MD27 and the transmission of the control data CD1 to CD27 (reset pulse) from the drive control unit 304.

### Exposure Processing of Line Pattern

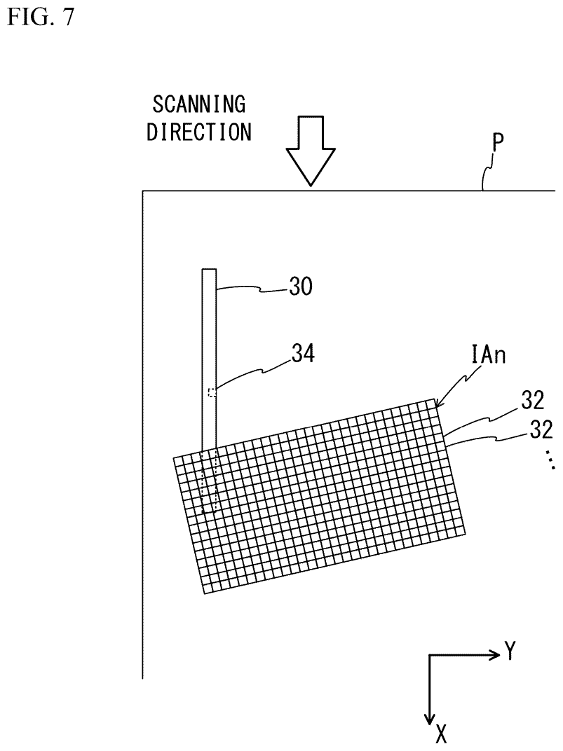

FIG. 7 schematically illustrates the projection area (light irradiation area group) IAn and an exposure target region (region to which a line pattern is exposed) 30 on the substrate P. In the present embodiment, the exposure target region 30 is scanned with respect to the projection area (light irradiation area group) IAn, and the DMD 10 turns on the micromirrors 10a corresponding to light irradiation areas 32 at a timing when the centers (referred to as spot positions) of the light irradiation areas 32 included in the projection area (light irradiation area group) IAn are positioned within the exposure target region 30.

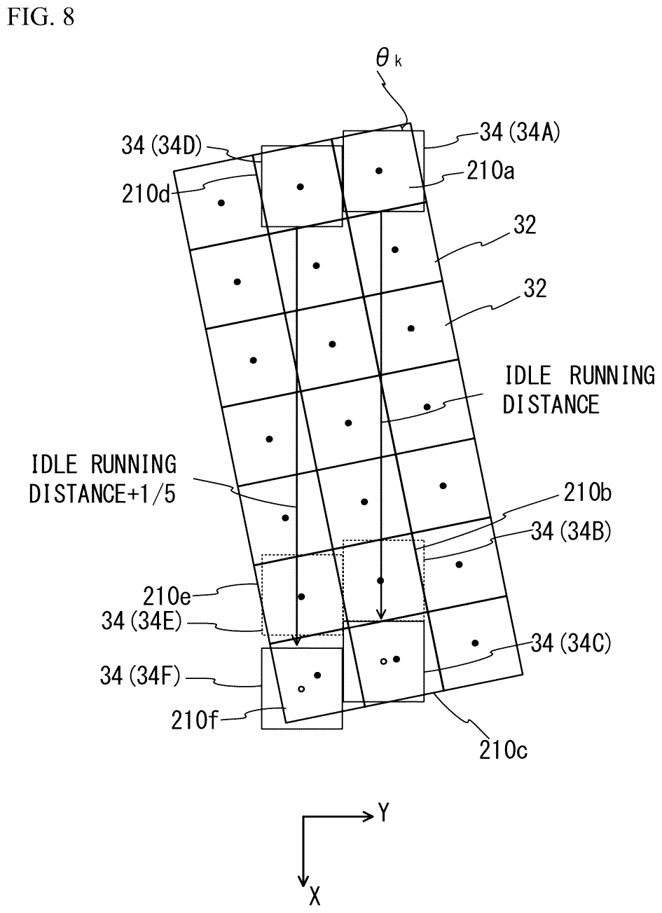

Here, as illustrated in FIG. 8, a rectangular region 34 that is a part of the line-shaped exposure target region 30 (see a broken line frame (reference numeral 34) in FIG. 7) will be discussed. The rectangular region 34 is, for example, a square region having a side of 1 for example. The light irradiation area 32 corresponding to each micromirror 10a is also a square region having a side of 1 μm. In addition, θk (inclination angle of the X′ axis with respect to the X axis) is an angle satisfying tan θk=⅕.

Hereinafter, the difference in how the rectangular region 34 is exposed in accordance with the difference in the scanning speed of the substrate P will be described.

(Case of First Scanning Speed)

As illustrated in FIG. 8, the first scanning speed is a speed such that the rectangular region 34 is located at the position 34C when the DMD 10 receives a reset pulse from the drive control unit 304 to turn on the micromirror corresponding to the light irradiation area 210a at the timing when the rectangular region 34 is located at the position 34A and the DMD 10 receives the next reset pulse to turn on the micromirror corresponding to the light irradiation area 210c. In this case, the rectangular region 34 moves by the idle running distance illustrated in FIG. 8 between the reset pulses. That is, the idle running distance is a distance between the rectangular region 34 located at the position 34A and the rectangular region 34 located at the position 34C.

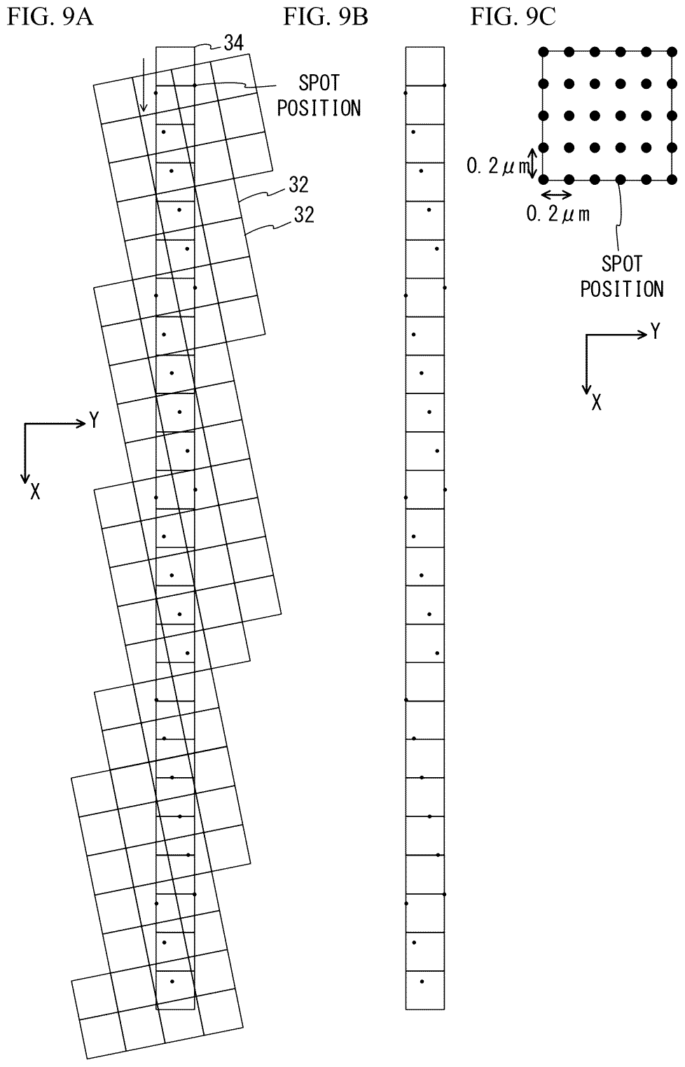

At the position 34B (see a broken-line rectangular frame) before the position 34C, the center position of the rectangular region 34 and the center position of the light irradiation area 210b coincide with each other. Also at the position 34A, the center position of the rectangular region 34 coincides with the center position of the light irradiation area 210a. Therefore, when the idle running distance is omitted, the positional relationship between the rectangular region 34 and the light irradiation area group in the case of scanning the substrate P at the first scanning speed can be expressed as illustrated in FIG. 9A. In FIG. 9A, the position of the rectangular region 34 each time the DMD 10 changes the states of the micromirrors 10a and the center positions (•) of the light irradiation areas 32 corresponding to the micromirrors 10a that expose the rectangular region 34 are illustrated. FIG. 9B is a diagram in which the light irradiation areas 32 are omitted from FIG. 9A. When the rectangular region 34 is exposed in this manner, the rectangular region 34 is exposed so that the spot positions are located in a 6×6 square arrangement (so that the spot positions are located on the lattice points aligned in the XY direction) with 26 pulses. In this case, the intervals between adjacent spot positions in the X-axis direction and the Y-axis direction are 0.2 μm.

(Case of Second Scanning Speed)

As illustrated in FIG. 8, the second scanning speed is a speed such that the rectangular region 34 is located at the position 34F when the DMD 10 receives a reset pulse from the drive control unit 304 to turn on the micromirror corresponding to the light irradiation area 210d at the timing when the rectangular region 34 is located at the position 34D and the DMD 10 receives the next reset pulse to turn on the micromirror corresponding to the light irradiation area 210f In this case, the rectangular region 34 moves by the idle running distance +⅕ (μm) illustrated in FIG. 8 between the reset pulses.

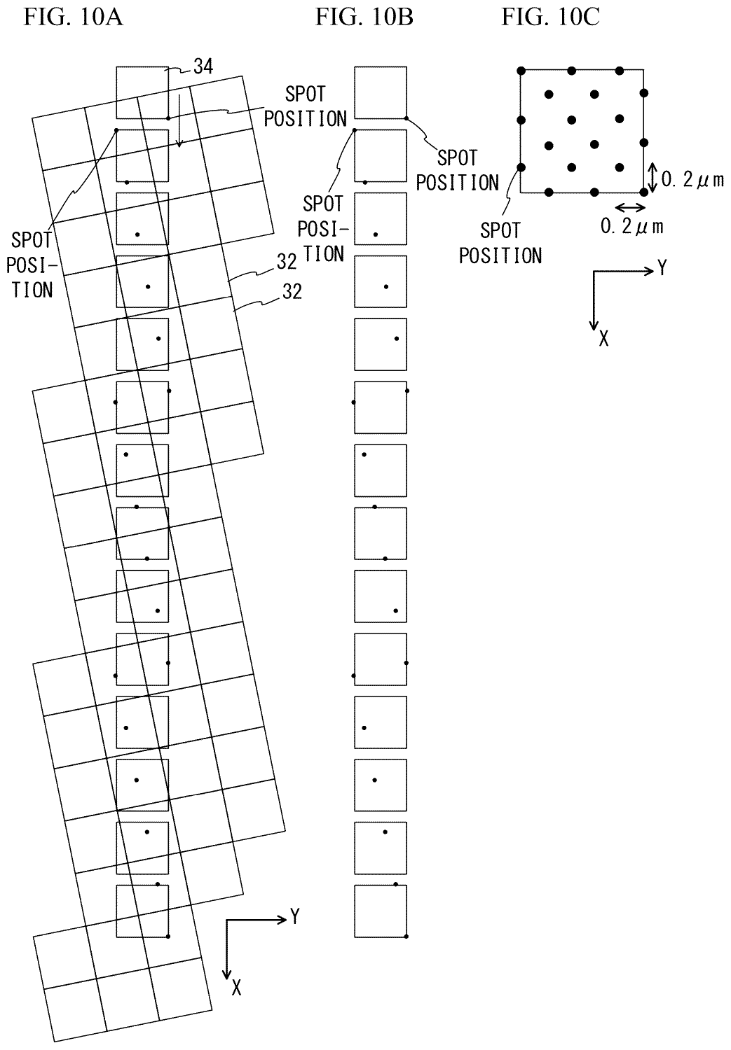

Here, at the position 34E before the position 34F, the center position of the rectangular region 34 coincides with the center position of the light irradiation area 210e. Further, the center position of the rectangular region 34 at the position 34D coincides with the center position of the light irradiation area 210d. Therefore, when the idle running distance is omitted, the positional relationship between the rectangular region 34 and the light irradiation area group in the case of scanning the substrate P at the second scanning speed can be expressed as illustrated in FIG. 10A. In FIG. 10A, the position of the rectangular region 34 each time the DMD 10 receives a reset pulse and changes the states of the micromirrors 10a, and the center positions (•) of the light irradiation areas 32 corresponding to the micromirrors 10a that expose the rectangular region 34 are illustrated. FIG. 10B is a diagram in which the light irradiation areas 32 are omitted from FIG. 10A. When the rectangular region 34 is exposed in this manner, the rectangular region 34 is exposed in a state where 18 spot positions are arranged (arranged in a staggered manner) with 14 pulses as illustrated in FIG. 10C. In this case, the intervals between adjacent spot positions in the X-axis direction and the Y-axis direction are 0.2 μm.

By adopting the staggered arrangement (see FIG. 10C) as described above, even if the number of pulses is smaller than that of the square arrangement (see FIG. 9C), the dense exposure is possible as in the case of the square arrangement. That is, with the staggered arrangement, exposure can be performed with a resolution equivalent to that in the case of the square arrangement. As a result, the scanning speed of the substrate P can be increased, and high throughput can be achieved. Therefore, in the present embodiment, Ok and the scanning speed of the substrate P are determined so that the spot positions are arranged in a staggered manner as illustrated in FIG. 10C. Hereinafter, the exposure illustrated in FIG. 10C is referred to as staggered exposure.

In the examples of FIG. 8 to FIG. 10C, the case where tan θk=⅕ is described, but in order to perform the staggered exposure, A is set to 5, 7, 9, 11, . . . where tan θk=1/A. Since the length of the DMD 10 can be effectively used by reducing the rotation angle (θk), the rotation angle is substantially set to 1:B (where B is an integer) in the exposure apparatus.

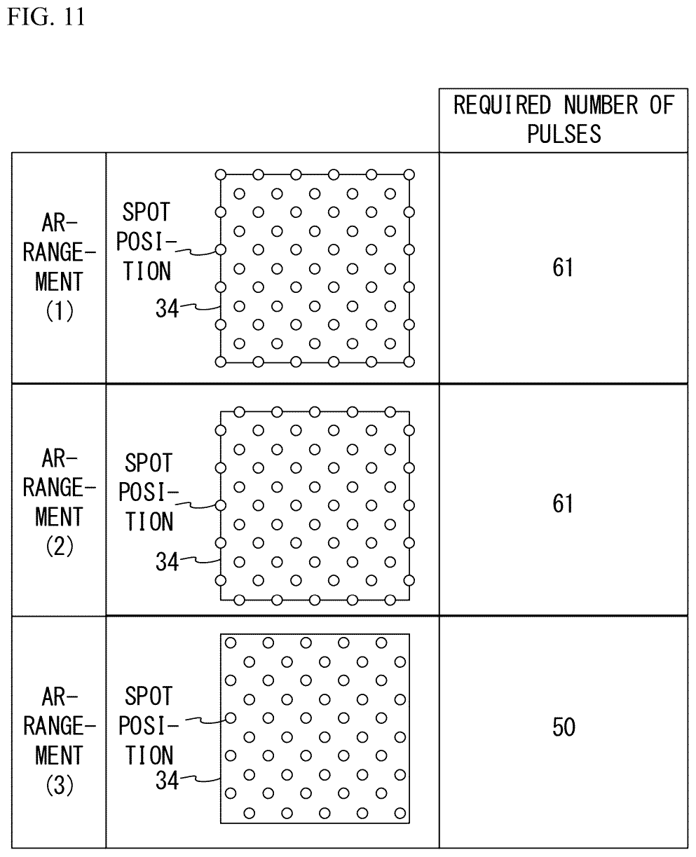

For example, when tan θk= 1/11 and the spot positions are arranged in a staggered manner in the rectangular region 34 (a side of 1 μm) (the intervals between adjacent spot positions in the X axis and Y axis directions=0.1 μm), the spot positions can be arranged at four corners of the rectangular region 34 as in the arrangement (1) of FIG. 11. Alternatively, the arrangement (2) in which the spot positions are not located at the four corners of the rectangular region 34 may be adopted. Alternatively, the arrangement (3) in which each spot position is located inside the rectangular region 34 may be adopted. As illustrated in FIG. 11, the required number of pulses is 61 in the arrangements (1) and (2), whereas the required number of pulses can be 50 in the arrangement (3). Therefore, for example, any one of the arrangements (1), (2) and (3) can be selected in accordance with the sensitivity of the resist applied on the substrate P.

### Exposure of Line Pattern Using Joint Section

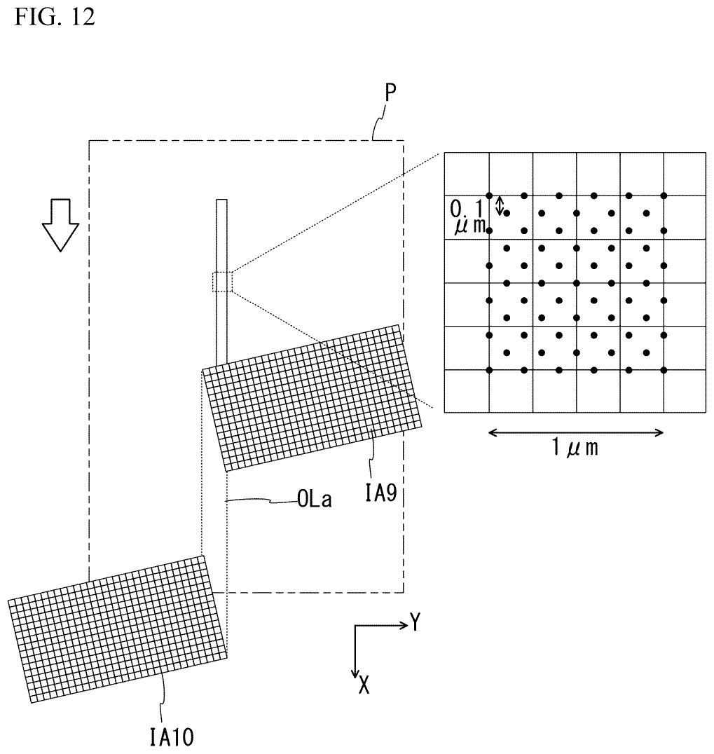

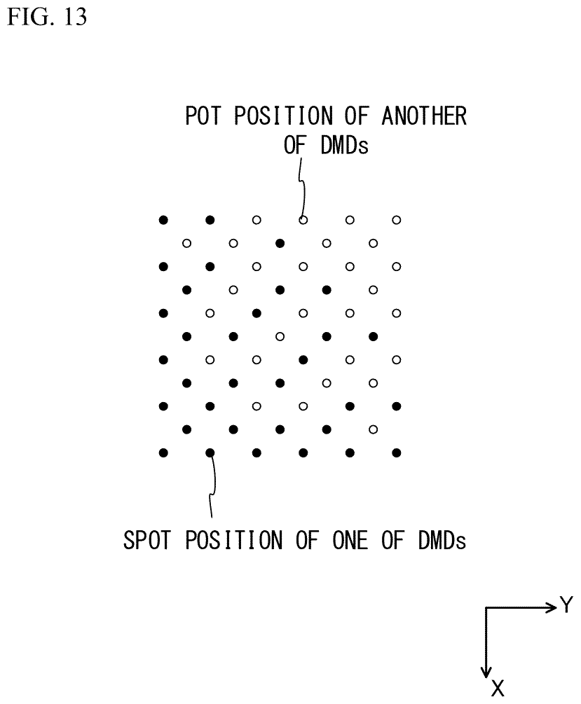

FIG. 12 schematically illustrates a state in which a line pattern is exposed in a joint section (for example, the joint section OLa). As illustrated in FIG. 12, even when the line pattern is exposed in the joint section OLa, the inside of the rectangular region 34 is subjected to the staggered exposure in the present embodiment. In this case, when the entire line pattern can be exposed by one DMD that exposes the joint section OLa (for example, the DMD corresponding to the projection area IA10), the line pattern may be exposed using only one of the DMDs. In addition, in a case where the line pattern cannot be exposed without using both DMDs, a portion that can be exposed by one DMD may be exposed, and the remaining portion may be exposed by the other DMD. Alternatively, the number of exposure pulses may be substantially equally shared by the two DMDs. In this case, spots (spot positions) to be exposed using the respective DMDs may be set randomly, or a ratio of spots to be exposed by one of the DMDs may be gradually increased or decreased in the non-scanning direction (Y-axis direction) or the scanning direction as indicated by “black circles (•)” and “white circles (∘)” in FIG. 13.

Although FIG. 12 illustrates the case where the joint section is exposed using two DMDs, this does not intend to suggest any limitation. For example, when a step-and-scan exposure is performed, in which the substrate P is scanned in the scanning direction for the projection area of one DMD, stepped in the non-scanning direction, and then scanned in the opposite direction from the previous step, the joint section is the area where the projection area of the DMD passes twice in succession. When the joint section is exposed, the staggered exposure can be performed as described above.

### Position Correction of Line Pattern

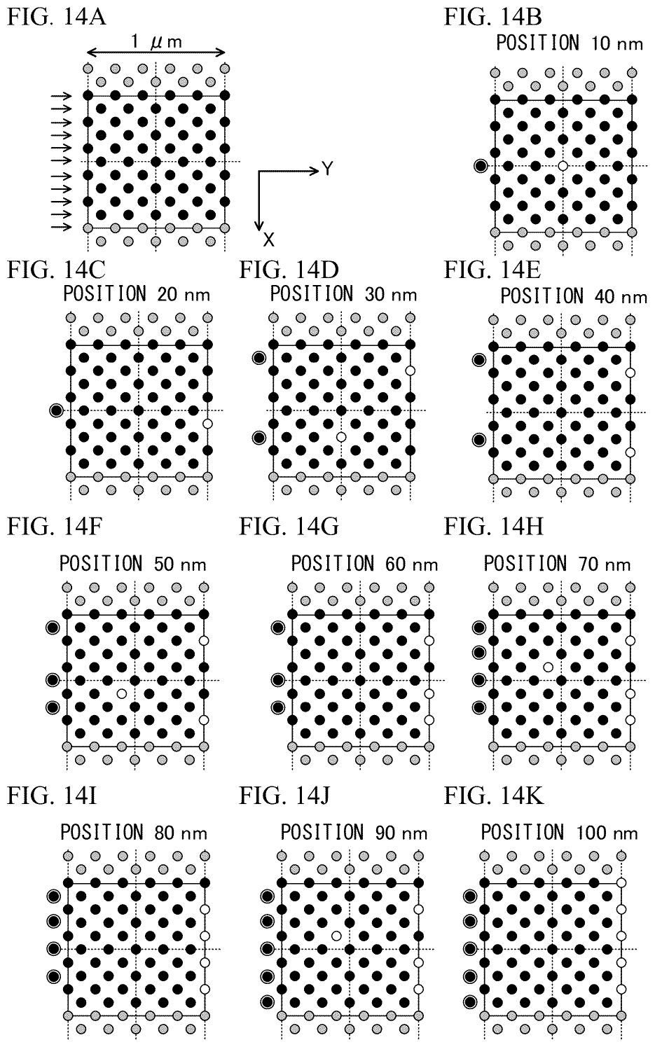

A description will be given of a method of correcting the position of a line pattern in the non-scanning direction in increments of 10 nm (=0.01 μm) in a case where a 1 μm-wide line pattern is formed by staggered shots in which the grids are arranged at intervals of 0.1 μm as illustrated in FIG. 14A.

When the line pattern of FIG. 14A is to be shifted in the left direction (−Y direction) by, for example, 100 nm, it can be achieved by eliminating the rightmost spot column (five spot positions indicated by white circles) and adding one new spot column (five spot positions indicated by double black circles) at the adjacent position on the left side (the side to which the line pattern is to be shifted) as illustrated in FIG. 14K.

On the other hand, when the line pattern is to be shifted leftward by 20 nm, which is ⅕ of the 100 nm, it can be achieved by eliminating one spot position (spot position indicated by a white circle) near the center of the rightmost spot column, and adding one new spot position (spot position indicated by a double black circle) to the left side as illustrated in FIG. 14C.

When the line pattern is to be shifted leftward by 10 nm, it can be achieved by eliminating the center spot position (the spot position indicated by a white circle) and adding one new spot position (the spot position indicated by a double black circle) to the left side as illustrated in FIG. 14B. In the line pattern, the shift amount can be made larger by eliminating/adding the spot position on or near the edge of the line pattern than by eliminating/adding the spot position in or near the center portion of the line pattern.

By changing the combination of adding one or more new spot positions on the left side and eliminating (or not eliminating) one or some of the originally existing spot positions, it is possible to shift the line pattern leftward in increments of 10 nm such as 10 nm, 20 nm, . . . , 90 nm, 100 nm as illustrated in FIG. 14B to FIG. 14K.

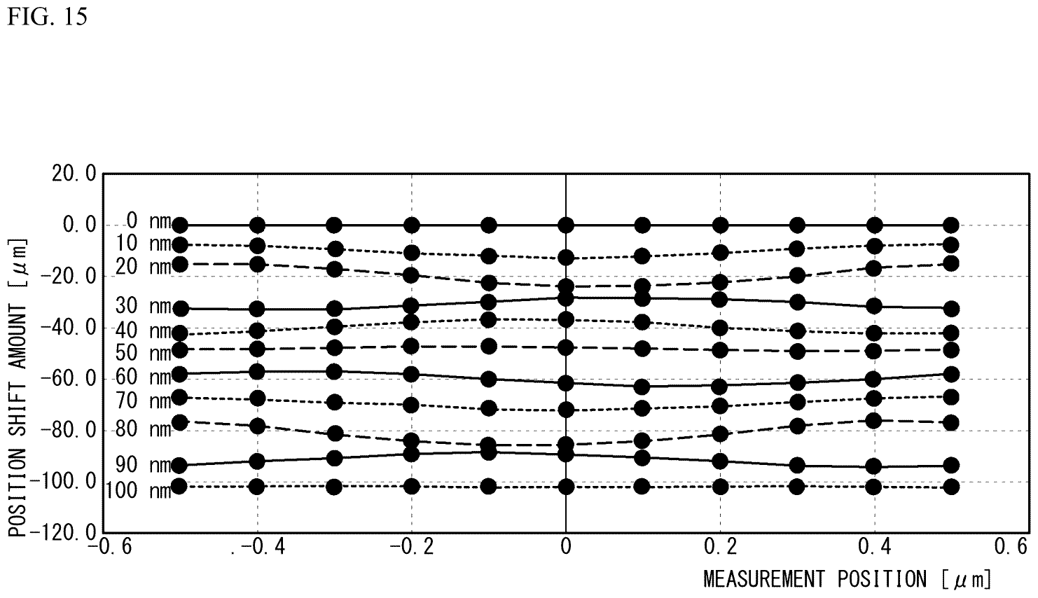

FIG. 15 is a graph presenting position measurement results when the position correction of the line pattern is performed by the methods of FIG. 14A to FIG. 14K. In this position measurement, the extent to which the position of the line pattern was corrected (shifted) in the Y-axis direction was measured at 11 positions in the X-axis direction indicated by arrows in FIG. 14A. It can be seen from FIG. 15 that the position of the line pattern can be corrected to a substantially desired position at any position in the X-axis direction.

In the present embodiment, when it is desired to correct the position of the line pattern by a distance equal to or less than the grid interval of the staggered arrangement (the intervals between the spot positions in the X and Y directions), the ON/OFF states of the micromirrors 10a of the DMD 10 are controlled so that the staggered exposure illustrated in FIG. 14B to FIG. 14K is performed. This allows the pattern to be exposed at a desired position. When performing correction to shift the position of the line pattern rightward (+Y direction), FIG. 14B to FIG. 14K are horizontally reversed and applied.

### Line Width Adjustment of Line Pattern

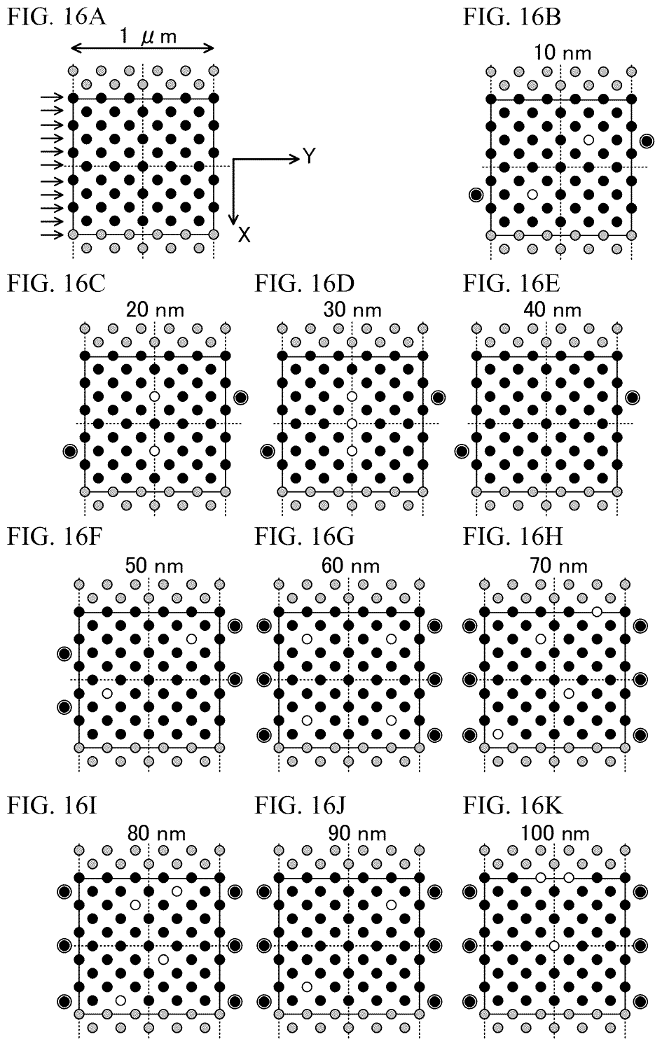

A description will be given of a method of adjusting the width (line width) of the line pattern in the non-scanning direction (Y-axis direction) in units of 10 nm (=0.01 μm) in a case where a 1 μm-wide line pattern is formed by a staggered arrangement in which the intervals between adjacent spot positions (the intervals in the X-axis and Y-axis directions) are 0.1 μm as illustrated in FIG. 16A. In the present embodiment, the line width is adjusted by a combination of arranging the same number of new spot positions at adjacent positions on both sides of the original line pattern (referred to as a reference pattern) illustrated in FIG. 16A and eliminating (or not eliminating) some spot positions of the reference pattern.

For example, as illustrated in FIG. 16B, new spot positions (double black circles) are arranged on both outside of the reference pattern of FIG. 16A, and two spot positions of the reference pattern are eliminated (white circles), whereby the line width can be increased by 10 nm. To increase the line width by 20 nm, as illustrated in FIG. 16C, new spot positions (double black circles) are arranged on both outside of the reference pattern, and two spot positions (spot positions different from those in FIG. 16B) of the reference pattern are eliminated.

To increase the line width by 30 nm, as illustrated in FIG. 16D, new spot positions (double black circles) are arranged on both outside of the reference pattern, and three spot positions in the central column of the reference pattern are eliminated. Further, to increase the line width by 40 nm, as illustrated in FIG. 16E, new spot positions (double black circles) are arranged one by one on both outside of the reference pattern while the spot positions of the reference pattern are not eliminated.

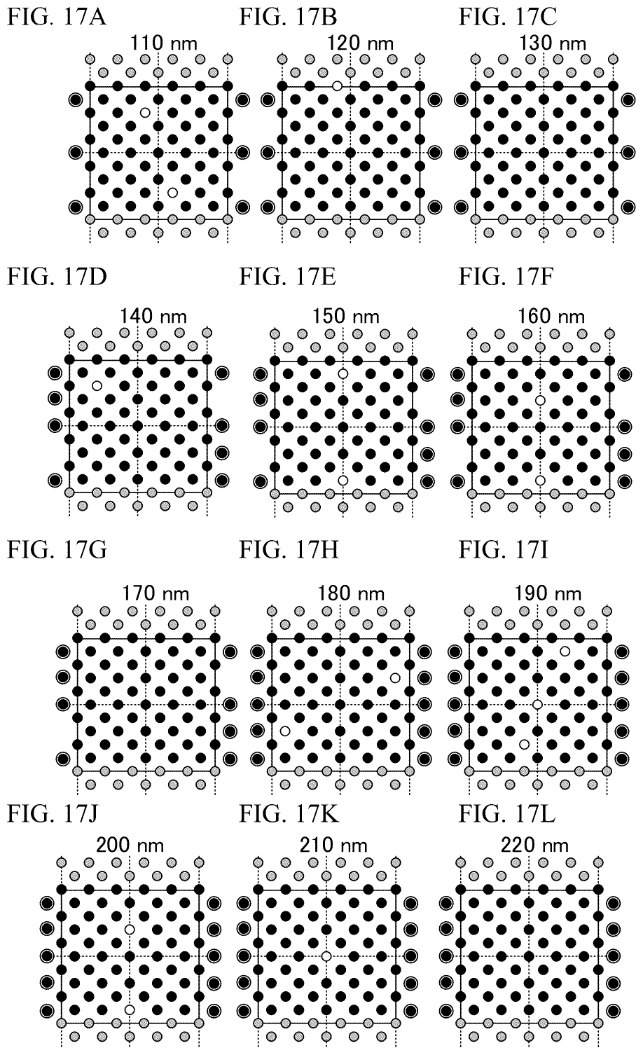

Also in the cases where the line width is increased by 50 nm, 60 nm, . . . , 220 nm, as illustrated in FIG. 16F to FIG. 16K and FIG. 17A to FIG. 17L, the line width can be adjusted by a combination of arranging the same number of new spot positions on both outside of the reference pattern of FIG. 16A and eliminating (or not eliminating) one or some of the spot positions of the reference pattern.

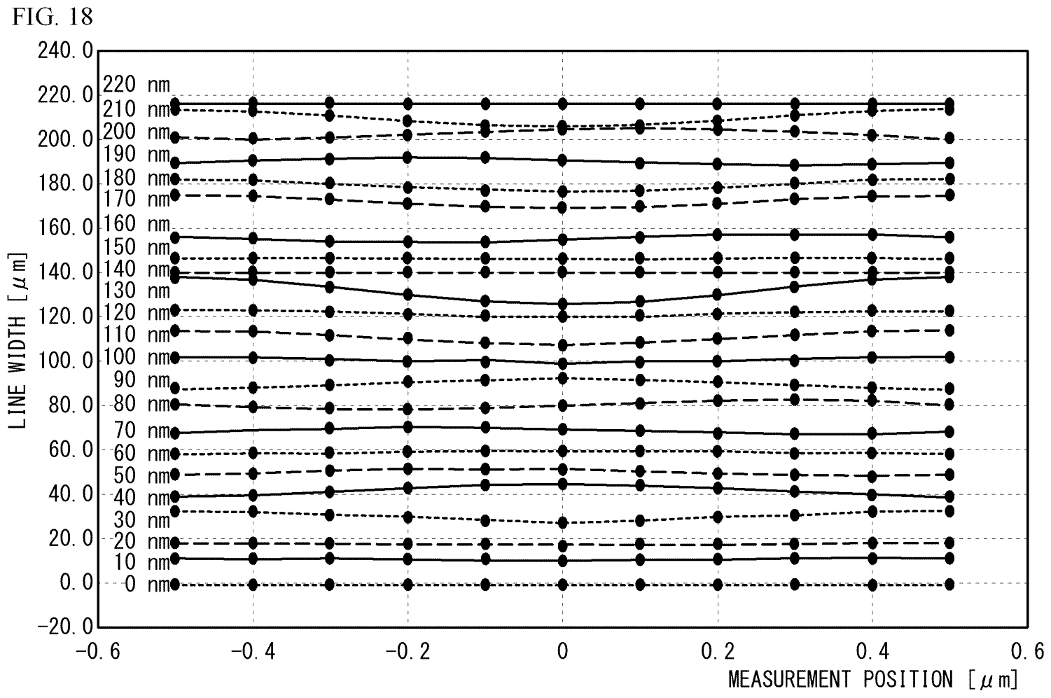

FIG. 18 is a graph presenting measurement results of the line width when the line width adjustment of the line pattern was performed using the methods of FIG. 16A to FIG. 17L. In this line width measurement, the line width (width in the Y-axis direction) of the line pattern was measured at 11 positions in the X-axis direction indicated by arrows in FIG. 16A. It can be seen from FIG. 18 that the line width of the line pattern can be adjusted to approximately a desired line width at any position in the X-axis direction.

In the present embodiment, when it is desired to adjust the line width of the line pattern by a size equal to or less than the grid interval (the intervals between the spot positions in the X and Y directions) of the staggered arrangement, the ON/OFF states of the micromirrors 10a of the DMD 10 are controlled so that exposure is performed as illustrated in FIG. 16B to FIG. 17L. This allows a desired line pattern to be obtained with high accuracy.

### Correction Based on Distortion Measurement Result

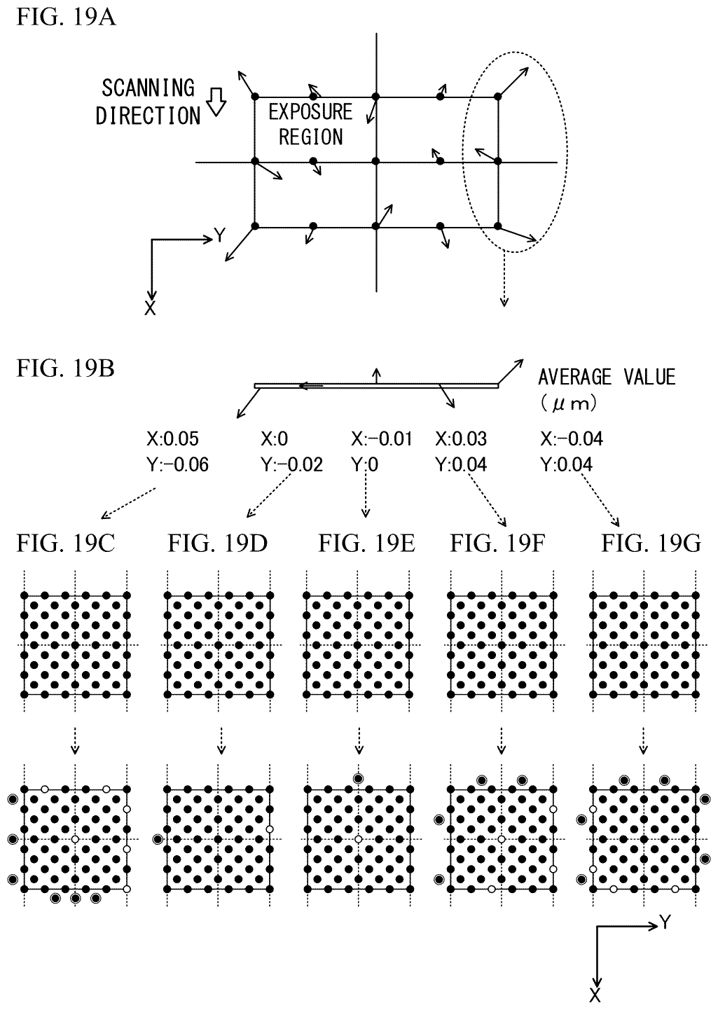

FIG. 19A illustrates an example of the results of measuring the distortion of a projected image of a module included in the exposure module by test exposure or the like. The arrow at each point indicates the direction and magnitude of the distortion. Measurement of distortion includes exposure of the substrate P using a test pattern (test exposure), detection of an image (transfer image) exposed on the substrate P, and creation of image distortion data (distortion data) using the detection result.

For example, when a square region having a side of 1 μm is exposed, the following exposure is performed in order to cancel the influence of distortion.

For example, when the distortion measurement results as presented in FIG. 19A are obtained, the average value of the distortions at the points whose positions in the non-scanning direction are the same is calculated. FIG. 19B illustrates an example of the calculation result of the average value of distortions for each position in the non-scanning direction. The average value of distortions for each position in the non-scanning direction is used to devise the spot position for each position in the non-scanning direction when exposing a square area. For example, when the average value of the distortions is 0.05 μm in the X direction and −0.06 μm in the Y direction as illustrated at the left end of FIG. 19B, three new spot positions (double black circles) are arranged on the left side and the lower side of the reference staggered exposure pattern (reference pattern) as illustrated in FIG. 19C, and five spot positions of the original square pattern are eliminated.

Also at other positions in the non-scanning direction, the spot positions are changed in accordance with the average value of the distortions as illustrated in FIG. 19D to FIG. 19G. As a result, the influence of distortion on exposure accuracy can be reduced. In this example, since the average value of the distortions in each position in the non-scanning direction is calculated and used for the processing, the processing can be simplified. In addition, by using the average value of distortions for each position in the non-scanning direction, it is possible to prevent, for example, a pattern extending in the scanning direction from being exposed in a jagged shape.

### Correction Based on Illuminance Distribution Measurement Result

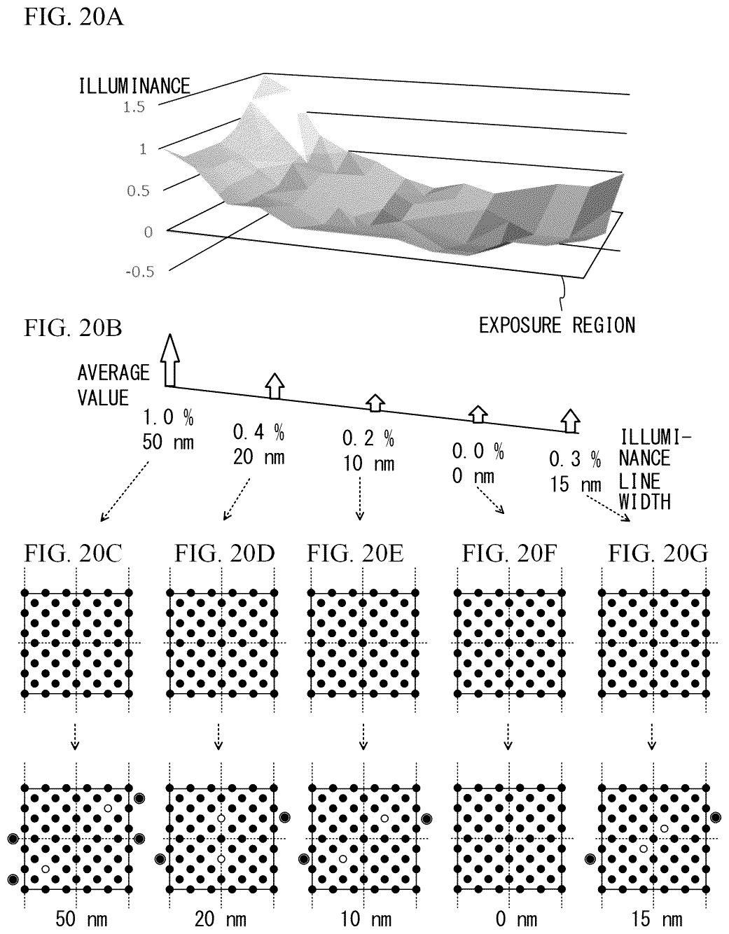

FIG. 20A presents an example of the measurement results of the illuminance distribution in one exposure region.

For example, when a square region having a side of 1 μm is exposed, the following exposure is performed in order to reduce the influence of the illuminance distribution.

When the measurement result of the illuminance distribution as illustrated in FIG. 20A is obtained, the average value of the illuminance at the points whose positions in the non-scanning direction are the same is calculated. FIG. 20B illustrates an example of the calculation result of the average value of the illuminance for each position in the non-scanning direction. In the example of FIG. 20B, it is assumed that 1.0%, 0.4%, 0.2%, 0.0%, and 0.3% are calculated from left to right. Further, in this example, based on the conditions of the photoresist, when the illuminance increases by 1.0%, the line width narrows by 50 nm, and the exposure is performed so that the line width increases as the illuminance increases. The method of widening the line width is the same as that illustrated in FIG. 16B to FIG. 17L.

For example, as illustrated at the left end of FIG. 20B, when the illuminance is 1.0%, in order to increase the line width by 50 nm, two new spot positions (double black circles) are arranged on both sides of the reference staggered exposure pattern (reference pattern), and two spot positions of the reference pattern are eliminated as illustrated in FIG. 20C.

Also at other positions in the non-scanning direction, the spot positions are changed from the reference pattern in accordance with the illuminance as illustrated in FIG. 20D to FIG. 20G. This makes it possible to reduce the influence of the illuminance distribution on the exposure accuracy. In this example, since the average value of the illuminance for each position in the non-scanning direction is calculated and used for the processing, the processing can be simplified. In addition, by using the average value of the illuminance for each position in the non-scanning direction, for example, it is possible to prevent a pattern extending in the scanning direction from being exposed in a jagged shape.

As described above in detail, in the present embodiment, there are provided the substrate holder 4B that holds the substrate P and moves, the exposure modules MU(A), MU(B), and MU(C) each having the DMD 10, and the drive control unit 304 that drives the substrate holder 4B in the scanning direction. The arrangement direction (X′ axis, Y′ axis) of the light irradiation areas in the light irradiation area group of the exposure module is inclined at an angle θk with respect to the scanning direction and the non-scanning direction, and the drive control unit 304 scans the substrate holder 4B at such a speed that staggered exposure is performed (the spot positions are arranged in a staggered manner) when a predetermined region of the substrate P is exposed. As a result, although the number of pulses is smaller (about 60%) than in the case where the spot positions are arranged in a square arrangement, exposure can be performed with a resolution equivalent to that in the square arrangement. The DMD 10 has a finite number of the micromirrors 10a in the scanning direction, but by exposing a pattern with a small number of pulses, it is possible to increase the possibility that a desired pattern can be exposed during one scanning. In addition, since the pattern can be exposed with a small number of pulses, the speed of the stage can be increased and the throughput of the exposure apparatus can be improved.

Further, in the present embodiment, since the staggered exposure is performed also when the joint section is exposed using two DMDs 10, the same pattern as that of the area other than the joint section can be exposed also in the joint section.

In addition, in the present embodiment, when it is desired to expose a line pattern by shifting the line pattern by a distance smaller than the grid interval, the DMD 10 is driven so that one or some of the spot positions in the line pattern before shifting is exposed outside the line pattern (the outside to which the line pattern is to be shifted). As a result, it is possible to easily expose a line pattern with the line pattern shifted by a distance smaller than the grid interval.

In addition, in the present embodiment, when it is desired to increase the line width of the line pattern by a size smaller than the grid interval, the DMD 10 is driven so that the same number of new spot positions are arranged on both outside of the original line pattern (reference pattern) and one or some spot positions of the original line pattern are decreased (or are not decreased). This allows the line width of the line pattern to be easily increased by a dimension smaller than the grid interval.

Further, in the present embodiment, the spot position of the line pattern is changed based on the distortion and the illuminance distribution of the module so that the influence of the distortion and the illuminance distribution is reduced. This makes it possible to easily reduce the influence of distortion and illuminance distribution on the exposure accuracy.

In the illumination unit ILU of the embodiment described above, in order to increase the resolution, NA and σ can be made variable, illumination conditions can be made variable, or an optical proximity correction (OPC) technique (a technique for overcoming the optical proximity effect by an auxiliary pattern) can be used.

Note that the disclosures of all publications, international publications, U.S. patent application publications, and U.S. patents relating to exposure apparatuses and the like cited in the above description are incorporated herein by reference.

The embodiments described above are examples of preferred embodiments of the present invention. However, the present invention is not limited thereto, and various modifications can be made without departing from the scope of the present invention.

What is claimed is:

1. An exposure apparatus comprising:
a substrate holder configured to hold and move a substrate;
a module including:
a spatial light modulator including light modulation elements that are two-dimensionally arranged;
an illumination unit configured to irradiate the spatial light modulator with illumination light; and
a projection unit configured to guide the illumination light from the light modulation elements to respective light irradiation areas that are two-dimensionally arranged in a first direction and a second direction perpendicular to the first direction on the substrate; and
a control unit configured to drive the substrate holder in a scanning direction,
wherein the light modulation elements are two-dimensionally arranged so as to be inclined at a predetermined angle θ (0°<θ<90°) with respect to the scanning direction and a non-scanning direction orthogonal to the scanning direction, and
wherein when a predetermined region of the substrate is exposed, the control unit scans the substrate holder at such a speed that spot positions on the predetermined region are arranged in a staggered arrangement, wherein the spot positions each indicate a center of the illumination light emitted from a corresponding one of the light modulation elements and irradiated to the predetermined region.

2. The exposure apparatus according to claim 1,
wherein the module is provided in plural, and
wherein when exposing a first region that can be exposed using a first module and a second module adjacent to the first module among the plural modules, the control unit scans the substrate holder at such a speed that arrangement of the spot positions in the first region is a staggered arrangement.

3. The exposure apparatus according to claim 2, wherein the control unit is configured to control the first module and the second module so that the first region is exposed by both of the first module and the second module.

4. The exposure apparatus according to claim 1, further comprising a receiving unit configured to receive a selection of one of the following:
exposing the predetermined region so that the spot positions are arranged in the staggered arrangement,
exposing the predetermined region so that the spot positions are arranged in a square arrangement in which the spot positions are arranged on lattice points aligned in the scanning direction and the non-scanning direction, and
exposing the predetermined region so that the spot positions are arranged in an inner staggered arrangement in which the spot positions are arranged in a staggered arrangement inside the predetermined region.

5. The exposure apparatus according to claim 1, wherein a region shifted from the predetermined region in the non-scanning direction is exposed by driving the spatial light modulator using drawing data in which one or some of the spot positions when exposing the predetermined region are changed to be located at positions that are adjacent to the predetermined region in the non-scanning direction and are outside the predetermined region.

6. The exposure apparatus according to claim 1, wherein a region wider than the predetermined region in the non-scanning direction is exposed by driving the spatial light modulator using drawing data changed so that one or more new spot positions are added in locations adjacent to both sides of the predetermined region in the non-scanning direction while reducing or not reducing one or some of the spot positions when exposing the predetermined region.

7. The exposure apparatus according to claim 1, wherein the predetermined region is exposed by generating drawing data changed so that a new spot position is added at a position that is adjacent to the predetermined region in the non-scanning direction and is outside the predetermined region while one or some of the spot positions when exposing the predetermined region in a state where there is no distortion of a projected image by the module are reduced or not reduced, based on a measurement result of the distortion of the projected image, and driving the spatial light modulator using the generated drawing data.

8. The exposure apparatus according to claim 7, wherein the distortion of the projected image is measured at a plurality of locations in a two-dimensional plane, and drawing data corresponding to each position in the non-scanning direction is generated based on an average of distortions at locations whose positions in the non-scanning direction are the same.

9. The exposure apparatus according to claim 1, wherein the predetermined region is exposed by generating drawing data changed so that new spot positions are added at positions adjacent to both sides of the predetermined region in the non-scanning direction while one or some of the spot positions when exposing the predetermined region in a state where an illumination distribution of the module is ideal are reduced or not reduced, based on a measurement result of the illumination distribution, and driving the spatial light modulator using the generated drawing data.

10. The exposure apparatus according to claim 1, wherein the predetermined angle θ is an angle where a value of A in tan θ=1/A is 5, 7, 9, or 11.

11. A control method comprising:
moving a substrate holder that is movable in two dimensions while holding a substrate at such a speed that spot positions each indicating a center of illumination light emitted from a corresponding one of light modulation elements with which a predetermined region of the substrate is irradiated are arranged in a staggered manner, the light modulation elements being two-dimensionally arranged so as to be inclined at a predetermined angle θ (0°<θ<90°) in a plane in the two dimensions.

12. The control method according to claim 11, wherein the predetermined angle θ is an angle where a value of A in tan θ=1/A is 5, 7, 9, or 11.

13. A device manufacturing method comprising:
exposing the substrate using the control method according to claim 11; and
developing the exposed substrate.
